(19) United States
(12) Patent Application Publication
(10) Pub. No.: US 2026/0239856 A1
(43) Pub. Date: Aug. 13, 2026

(54) DISPLAY PANEL, MANUFACTURING METHOD THEREOF AND DISPLAY DEVICE

(71) Applicant: HKC CORPORATION LIMITED, Shenzhen (CN)

(72) Inventors: XIUFENG ZHOU, Shenzhen (CN); Zhisheng XIE, Shenzhen (CN); Yangling TANG, Shenzhen (CN); Qin LIANG, Shenzhen (CN); Pei XU, Shenzhen (CN)

(21) Appl. No.: 19/461,739

(22) Filed: Jan. 28, 2026

(30) Foreign Application Priority Data
Feb. 10, 2025 (CN) 202510146658.1

(51) Int. Cl. H10K 59/80; H10K 59/12; H10K 59/122; H10K 71/60; H10K 102/00

(52) U.S. Cl. CPC H10K 59/80516; H10K 59/1201; H10K 59/122; H10K 59/80517; H10K 71/60; H10K 2102/351

(57) ABSTRACT

Disclosed are a display panel, a manufacturing method thereof and a display device. The display panel includes a substrate, a pixel-defining layer and a plurality of light-emitting elements. Each of the plurality of light-emitting elements further includes an anode auxiliary electrode, the anode auxiliary electrode is disposed between the anode and the light-emitting functional layer. Each of the plurality of first partition structures includes a conductive portion and a partition portion, the partition portion is disposed on the conductive portion, a radial width of the partition portion is greater than that of the conductive portion, and each of the plurality of first partition structures is configured to separate separate at least one of: (a) the anode auxiliary electrodes, (b) the light-emitting functional layers, of two adjacent light-emitting elements when depositing an entire surface of the anode auxiliary electrodes and the light-emitting functional layer.

### CROSS-REFERENCE TO RELATED APPLICATIONS

The present disclosure claims the priority and benefit of Chinese patent disclosure number 2025101466581, titled "Display Panel, Manufacturing Method Thereof and Display Device" and filed on February 10, 2025 with China National Intellectual Property Administration, the entire contents of which are incorporated herein by reference.

### TECHNICAL FIELD

The present disclosure relates to the technical field of display, and more particularly relates to a display panel, a manufacturing method thereof and a display device.

### BACKGROUND

The description provided in this section is intended for the mere purpose of providing background information related to the present disclosure but does not necessarily constitute prior art.

Organic Light-Emitting Diode (hereinafter referred to as OLED) display device is widely used in various fields due to their light weight, wide viewing angle, fast response, low temperature resistance, high luminous efficiency, and the ability to produce curved flexible displays. As mass production technology becomes increasingly mature, OLED display panel is gradually becoming mainstream real-world panels.

However, due to process reasons, when etching the anode of a light-emitting element of the OLED display panel, the protective layer may not be removed cleanly, resulting in residues. The above problem may lead to an increase in the contact resistance between the anode and the organic material in the light-emitting functional layer, thereby causing the driving voltage of the light-emitting element to increase or the lifespan of the light-emitting element to reduce rapidly.

### SUMMARY

The purpose of the present disclosure is to provide a display panel, a manufacturing method thereof and a display device, which improve the film interface between the anode and the light-emitting functional layer by adding an anode auxiliary electrode between the anode and the light-emitting functional layer, thereby improving the luminous efficiency and service life of the plurality of light-emitting elements.

The present disclosure discloses a display panel, including a substrate, a pixel-defining layer and a plurality of light-emitting elements. The pixel-defining layer is disposed on the substrate and provided with a plurality of opening areas. The plurality of light-emitting elements are arranged in an array on the substrate and respectively located in the plurality of opening areas. Each of the plurality of light-emitting elements includes an anode, a light-emitting functional layer and a cathode, the anode is disposed on the substrate, the light-emitting functional layer is disposed on the anode, and the cathode is disposed on the light-emitting functional layer. Each of the plurality of light-emitting elements further includes an anode auxiliary electrode, the anode auxiliary electrode is disposed between the anode and the light-emitting functional layer, the anode auxiliary electrode is formed of one or more of metal, metal alloy, or metal oxide. The display panel further includes a plurality of first partition structures, disposed on the pixel-defining layer, each of the plurality of first partition structures includes a conductive portion and a partition portion, the partition portion is disposed on the conductive portion, a radial width of the partition portion is greater than that of the conductive portion, and each of the plurality of first partition structures is configured to separate separate at least one of: (a) the anode auxiliary electrodes, (b) the light-emitting functional layers, of two adjacent light-emitting elements when depositing an entire surface of the anode auxiliary electrodes and the light-emitting functional layer.

The present disclosure discloses a method for manufacturing a display panel, including:

providing a substrate;

forming an anode by depositing and patterning on the substrate;

forming a pixel-defining layer by depositing and patterning, and forming a plurality of opening areas;

forming a plurality of first partition structures by sequentially depositing and patterning a conductive portion material and a partition portion material on the pixel-defining layer;

forming, by depositing an anode auxiliary electrode material and a light-emitting functional layer material, an anode auxiliary electrode and a light-emitting functional layer in each of the plurality of opening areas through the plurality of first partition structures;

forming a cathode to form a plurality of light-emitting elements in the plurality of opening areas; and

forming a display panel.

The present disclosure further discloses a display device, including a display panel and a driving circuit configured to drive the display panel. The display panel includes a substrate, a pixel-defining layer and a plurality of light-emitting elements. The pixel-defining layer is disposed on the substrate and provided with a plurality of opening areas. The plurality of light-emitting elements are arranged in an array on the substrate and respectively located in the plurality of opening areas. Each of the plurality of light-emitting elements includes an anode, a light-emitting functional layer and a cathode, the anode is disposed on the substrate, the light-emitting functional layer is disposed on the anode, and the cathode is disposed on the light-emitting functional layer. Each of the plurality of light-emitting elements further includes an anode auxiliary electrode, the anode auxiliary electrode is disposed between the anode and the light-emitting functional layer, the anode auxiliary electrode is formed of one or more of metal, metal alloy, or metal oxide. The display panel further includes a plurality of first partition structures, disposed on the pixel-defining layer, each of the plurality of first partition structures includes a conductive portion and a partition portion, the partition portion is disposed on the conductive portion, the radial width of the partition portion is greater than that of the conductive portion, and each of the plurality of first partition structures is configured to separate at least one of: (a) the anode auxiliary electrodes, (b) the light-emitting functional layers, of two adjacent light-emitting elements when depositing an entire surface of the anode auxiliary electrodes and the light-emitting functional layer.

In the present disclosure, an anode auxiliary electrode is added to the anode and the light-emitting functional layer. During the deposition process, the anode auxiliary electrode has a good contact interface with the anode. Although reside issues may exist on the anode, the problem of increased contact resistance does not arise since the anode auxiliary electrode also has conductive properties and is in full contact with the anode. The advantage of the anode auxiliary electrode is that the anode auxiliary electrode may be isolated by the plurality of first partition structures without etching, allowing the anode auxiliary electrode of each of the plurality of light-emitting elements to be independently arranged, thereby avoiding a series of problems caused by etching to the anode auxiliary electrode such as etching residue and etching oxidation. Importantly, the plurality of first partition structures are configured to process the anode auxiliary electrode and the subsequent light-emitting functional layer under the same ambient condition. After the anode auxiliary electrode is formed, the etching process is not required, and the light-emitting functional layer is directly deposited, avoiding the influence of the intermediate process on the film interface between the anode auxiliary electrode and the light-emitting functional layer, thereby improving the light-emitting efficiency and service life of the plurality of light-emitting elements.

### BRIEF DESCRIPTION OF DRAWINGS

The included drawings are provided for further understanding of embodiments of the present disclosure, constitute a part of the specification, illustrate embodiments of the present disclosure, and together with the text description, explain principles of the present disclosure. Obviously, the drawings in the following description are merely some embodiments of the present disclosure. For those of ordinary skill in the art, other drawings may be obtained based on these drawings without creative labor. In the drawings:

FIG. 1 is a schematic diagram of a display panel of a first embodiment of the present disclosure.

FIG. 2 is a schematic diagram of steps of a method for manufacturing a display panel according to the first embodiment of the present disclosure.

FIG. 3 is a schematic diagram of a display panel of a second embodiment of the present disclosure.

FIG. 4 is a schematic diagram of the first partition structure and the second partition structure of the present disclosure.

FIG. 5 is a schematic diagram of a light-emitting element of a first embodiment of the present disclosure.

FIG. 6 is a schematic diagram of an anode of a second embodiment of the present disclosure.

FIG. 7 is a schematic diagram of another display panel of a second embodiment of the present disclosure.

FIG. 8 is a schematic diagram of steps of a method for manufacturing a display panel according to the second embodiment of the present disclosure.

FIG. 9 is a schematic diagram of manufacturing a display panel according to a second embodiment of the present disclosure.

FIG. 10 is a schematic diagram of a display device according to the present disclosure.

Reference Numerals: 100, display panel; 101, opening area; 102, non-opening area; 110, substrate; 120, pixel-defining layer; 121, partition groove; 122, first partition structure; 1221, conductive portion; 1222, partition portion; 130, light-emitting element; 131, anode; 1311, first transparent electrode layer; 1312, first reflective electrode layer; 1313, second transparent electrode layer; 1314, first electrode layer; 132, light-emitting functional layer; 1321, hole-injection layer; 1322, hole-transport layer; 1323, an electron-blocking layer; 1324, light-emitting layer; 1325, hole-blocking layer; 1326, electron-transport layer; 1327, electron-injection layer; 133, cathode; 134, anode auxiliary electrode; 1341, first auxiliary electrode layer; 1342, second reflective electrode layer; 1343, second auxiliary electrode layer; 140, partition layer; 141, second partition structure; 150, pixel driving layer; 200, display device; 210, driving circuit.

### DETAILED DESCRIPTION OF EMBODIMENTS

It should be understood that the terminology, specific structures, and functional details disclosed herein are merely used to describe specific embodiments and are illustrative. However, the present disclosure may be implemented through many alternative forms and should not be construed as limited solely to the embodiments described herein.

In the description of the present disclosure, terms such as "first" and "second" are used solely for descriptive purposes and should not be interpreted as indicating relative importance or implicitly specifying the number of technical features indicated. Thus, unless otherwise specified, features qualified by "first" or "second" may explicitly or implicitly include one or more such features. "A plurality of" means two or more. Additionally, directional or positional terms such as "upper," "lower," "left," "right," "vertical," or "horizontal" are described based on orientations or relative positional relationships shown in the accompanying drawings, which are used for simplified description to facilitate understanding of the present application and do not imply that the devices or elements described should have specific orientations or be constructed or operated in specific orientations. These terms should not be construed as limiting the present disclosure. For those skilled in the art, the specific meaning of the above terms in the context of the present disclosure may be understood according to the specific situation.

The present disclosure is described below in detail with reference to the accompanying drawings and optional embodiments.

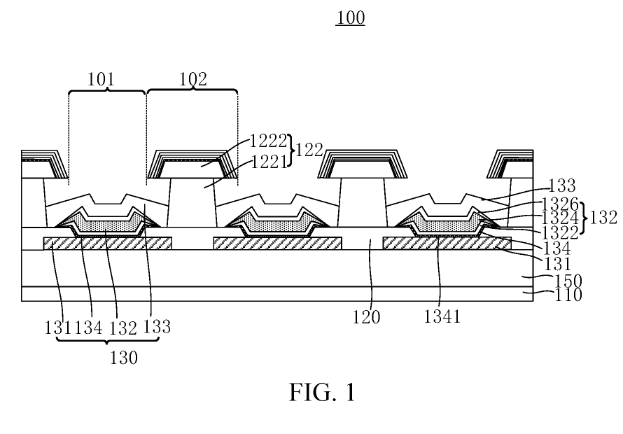

FIG. 1 is a schematic diagram of a display panel of a first embodiment of the present disclosure. As shown in FIG. 1, the present disclosure discloses a display panel. The display panel 100 includes a substrate 110, a pixel-defining layer 120, a plurality of light-emitting elements 130 and a plurality of first partition structures 122. The pixel-defining layer 120 is disposed on the substrate 110 and the pixel-defining layer 120 is provided with a plurality of opening areas 101. The plurality of light-emitting elements 130 are arranged in an array on the substrate 110 and respectively located in the plurality of opening areas 101. Each of the plurality of light-emitting elements 130 includes an anode 131, a light-emitting functional layer 132 and a cathode 133, the anode 131 is disposed on the substrate 110, the light-emitting functional layer 132 is disposed on the anode 131, and the cathode 133 is disposed on the light-emitting functional layer 132. Each of the plurality of light-emitting elements 130 further includes an anode auxiliary electrode 134, the anode auxiliary electrode 134 is disposed between the anode 131 and the light-emitting functional layer 132, the anode auxiliary electrode 134 is formed of one or more of metal, metal alloy, or metal oxide. The plurality of first partition structures 122 are disposed on the pixel-defining layer 120, each of the plurality of first partition structures 122 includes a conductive portion 1221 and a partition portion 1222, the partition portion 1222 is disposed on the conductive portion 1221, the radial width of the partition portion 1222 is greater than that of the conductive portion 1221, and each of the plurality of first partition structures 122 is configured to separate at least one of: (a) the anode auxiliary electrodes 134, (b) the light-emitting functional layers 132, of two adjacent light-emitting elements 130 when depositing an entire surface of the anode auxiliary electrodes 134 and the light-emitting functional layer 132.

In the present disclosure, an anode auxiliary electrode 134 is added to the anode 131 and the light-emitting functional layer 132. During the deposition process, the anode auxiliary electrode 134 has a good contact interface with the anode 131. Although residue issues may exist on the anode 131, the problem of increased contact resistance does not arise since the anode auxiliary electrode 134 also has conductive properties and is in full contact with the anode 131. The advantage of the anode auxiliary electrode 134 is that the anode auxiliary electrode 134 may be isolated by the plurality of first partition structures 122 without etching, allowing the anode auxiliary electrode 134 of each of the plurality of light-emitting elements 130 to be independently arranged, thereby avoiding a series of problems caused by etching on the anode auxiliary electrode 134, such as etching residue and etching oxidation. Importantly, the plurality of first partition structures 122 are configured to process the anode auxiliary electrode 134 and the subsequent light-emitting functional layer 132 under the same ambient conditions. After the anode auxiliary electrode 134 is formed, the etching process is not required, and the light-emitting functional layer 132 is directly deposited, avoiding the influence of the intermediate process on the film interface between the anode auxiliary electrode 134 and the light-emitting functional layer 132, thereby improving the light-emitting efficiency and service life of the plurality of light-emitting elements 130.

Specifically, each of the plurality of first partition structures 122 is configured to separate the anode auxiliary electrodes 134 and the light-emitting functional layer 132 of two adjacent light-emitting elements 130 when the anode auxiliary electrode 134 and the light-emitting functional layer 132 are deposited over the entire surface. The anode auxiliary electrodes 134 and the light-emitting functional layer 132 are respectively neither connected to the conductive portion 1221, and the cathode 133 is connected to the conductive portions 1221 of two adjacent first partition structures 122.

It is worth mentioning that the plurality of first partition structures 122, in some embodiments, is a key structure used in the mask-less evaporation technology, commonly known as a conductive partition structure and is usually used to partition the light-emitting functional layer 132 and the cathode 133. The conductive partition structure may also be called a partition structure etc. The first partition structure 122 is mainly formed by a narrower conductive portion 1221 arranged at the bottom and a wider partition portion 1222 arranged at the top, so that in the process of evaporating the material, the plurality of first partition structures 122 are used as a metal mask to form a patterned anode auxiliary electrode 134, a light-emitting functional layer 132, etc. in the required area, such as the plurality of opening areas 101.

Considering that the conductive portion 1221 located at the bottom of the plurality of first partition structures 122 has the ability to conduct electricity, it is generally formed of metal material. Therefore, when the anode auxiliary electrode 134 is partitioned, it is necessary to prevent the anode auxiliary electrode 134 from being electrically connected to the conductive portion 1221. Since the conductive portion 1221 is also configured to connect the cathode 133 of two adjacent light-emitting elements 130, the cathode 133 of the plurality of light-emitting elements 130 is connected to form a mesh electrode, thereby reducing resistance. Of course, in this case, it is also necessary to ensure that the light-emitting functional layer 132 is not connectied to the conductive portion 1221.

In some embodiments, the evaporation angle may be controlled so that a certain distance exists between the anode auxiliary electrode 134 and the light-emitting functional layer 132 and the conductive portion 1221, respectively, so that the anode auxiliary electrode 134 and the light-emitting functional layer 132 are not connected to the conductive portion 1221.

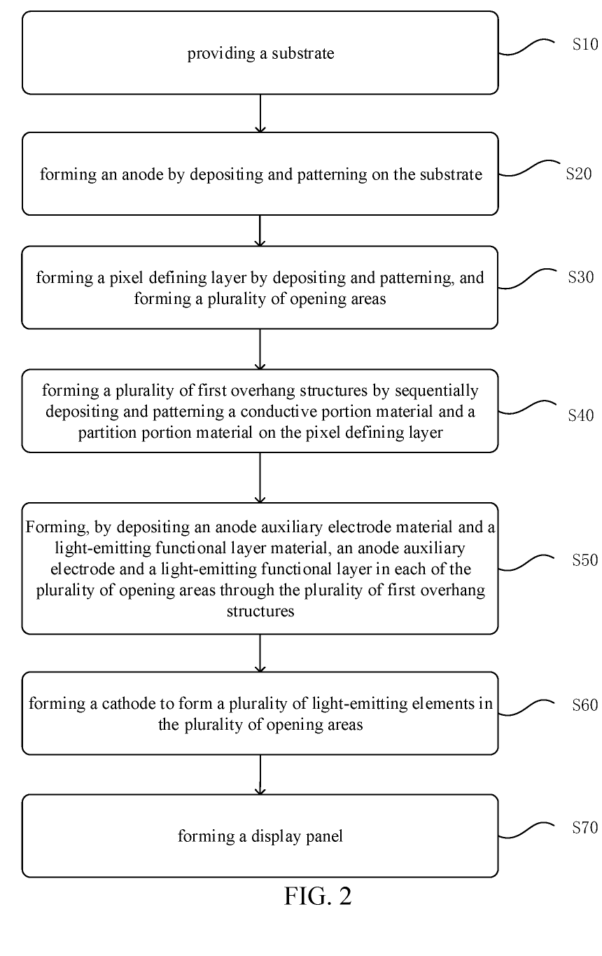

FIG. 2 is a schematic diagram of steps of a method for manufacturing a display panel according to the first embodiment of the present disclosure. As shown in FIG. 2, the present disclosure discloses a method for manufacturing a display panel corresponding to the above-mentioned display panel. The method for manufacturing a display panel includes:

S10: providing a substrate;

S20: forming an anode by depositing and patterning on the substrate;

S30: forming a pixel-defining layer by depositing and patterning, and forming a plurality of opening areas;

S40: forming a plurality of first partition structures by sequentially depositing and patterning a conductive portion material and a partition portion material on the pixel-defining layer;

S50: forming, by depositing an anode auxiliary electrode material and a light-emitting functional layer material, an anode auxiliary electrode and a light-emitting functional layer in each of the plurality of opening areas through the plurality of first partition structures;

S60: forming a cathode to form a plurality of light-emitting elements in the plurality of opening areas; and

S70: forming a display panel.

In some embodiments, although the anode auxiliary electrode 134 is added, the process steps of the anode auxiliary electrode 134 do not need to be added. The anode auxiliary electrode 134 only needs to be evaporated in sequence with the light-emitting functional layer 132. Combined with the mask-less evaporation technology of the display panel 100, the patterning process of the anode auxiliary electrode 134 is realized by means of the conductive partition structure of the evaporated light-emitting functional layer 132. The anode auxiliary electrode 134 is configured to improve the film interface between the anode 131 and the light-emitting functional layer 132 by realizing the formation of the anode auxiliary electrode 134 without adding additional processes. It is important that the anode auxiliary electrode 134 and the subsequent light-emitting functional layer 132 are processed under the same ambient conditions. After the anode auxiliary electrode 134 is formed, no etching process is required, and the light-emitting functional layer 132 is directly deposited, thereby avoiding the influence of the intermediate process on the film interface between the anode auxiliary electrode 134 and the light-emitting functional layer 132.

Specifically, in the above-mentioned process of forming the plurality of first partition structures 122, by continuously depositing an entire surface of conductive portion 1221 material and partition portion 1222 material, the partition portion 1222 material in the plurality of opening areas 101 and the area other than the plurality of first partition structures 122 is removed by using photolithography technology, and the partition portion 1222 in the plurality of first partition structures 122 is retained. Then, the conductive portion 1221 is wet-etched using the partition portion 1222 as a protective layer, and the side etching of the conductive portion 1221 caused by the wet etching process causes the conductive portion 1221 to be over-etched at the edge of the partition portion 1222, so that the width of the conductive portion 1221 is greater than the width of the partition portion 1222, and a conductive partition structure similar to an "overhang" shape is formed, the "overhang" shape is wide at the top and narrow at the bottom.

In some embodiments, the anode auxiliary electrode 134 may include only one electrode layer, namely the first auxiliary electrode layer 1341, and the first auxiliary electrode layer 1341 is disposed on the second transparent electrode layer 1313 and directly contacts the second transparent electrode layer 1313; the first auxiliary electrode layer 1341 of the present embodiment may be selected as metal oxide material with a high work function such as indium tin oxide (hereinafter referred to as ITO), indium zinc oxide (hereinafter referred to as IZO), etc., or may be selected as a metal or metal alloy material with a high work function such as Pt, Ni, Au, etc. However, considering that the metal or metal alloy material has the characteristic of being opaque when the thickness thereof is thick, it is necessary to limit the thickness of the metal or metal alloy material, that is, the thickness of the first auxiliary electrode layer 1341 should not exceed 30 nm (300 angstroms). Of course, the thickness of the first auxiliary electrode layer 1341 may not be too thin, and at least needs to be greater than or equal to 10 angstroms.

After the light-emitting functional layer 132 is partitioned, during the process of forming the cathode 133, the cathode 133 is also partitioned due to the partitioning effect of the plurality of first partition structures 122. The cathode 133 of the plurality of light-emitting elements 130 generally needs to be set as an entire surface to have the same voltage, so that the brightness of the plurality of light-emitting elements 130 may be controlled by adjusting the voltage of the anode 131. Therefore, in this solution, by controlling the evaporation angle, the cathode 133 extends from the plurality of opening areas 101 to the non-opening area 102, so that the cathode 133 is electrically connected to the conductive portion 1221, and the cathode 133 is arranged in a mesh pattern through the conductive portion 1221.

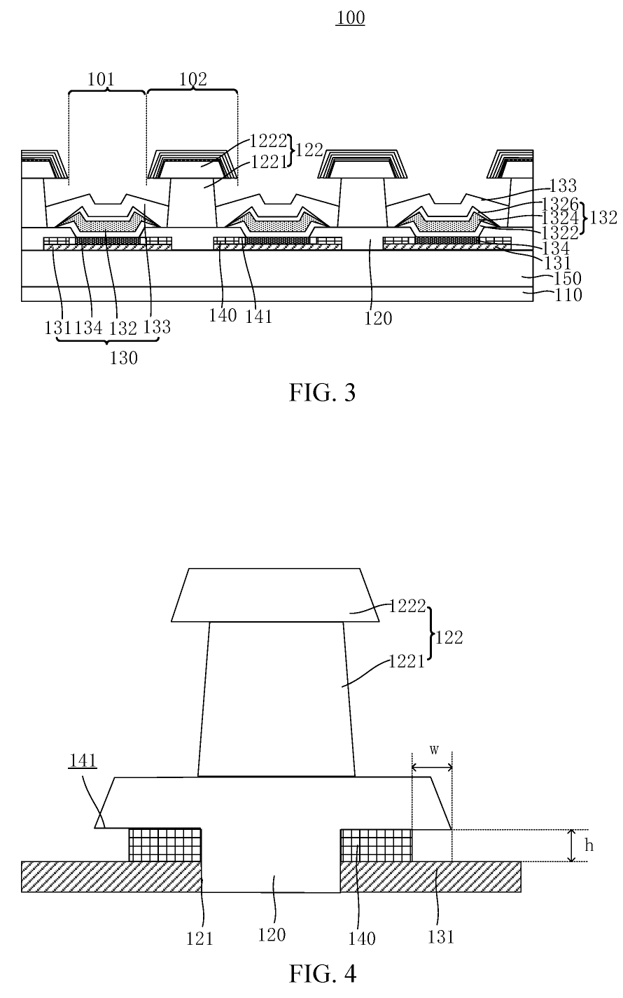

FIG. 3 is a schematic diagram of a display panel of a second embodiment of the present disclosure. FIG. 4 is a schematic diagram of the first partition structure and the second partition structure of the present disclosure. As shown in FIGS. 3 and 4, in addition to the above embodiments, the present embodiment further includes a plurality of second partition structures 141, the plurality of second partition structures 141 are disposed below the plurality of first partition structures 122. The plurality of second partition structures 141 are configured to partition the anode auxiliary electrode 134, while the plurality of first partition structures 122 are configured to partition the light-emitting functional layer 132.

Specifically, in the process of the plurality of light-emitting elements 130 of the display panel 100, the anode 131 is generally formed first, and the pixel-defining layer 120 is formed on the anode 131. After the pixel-defining layer 120 is patterned, the required pixel area, i.e., the opening area 101, is isolated. The plurality of opening areas 101 are configured to form the subsequent light-emitting functional layer 132 and the cathode 133. After the anode 131 is deposited, it needs to undergo a patterning process and a subsequent patterning process of the pixel-defining layer 120 before the light-emitting functional layer 132 is formed. The patterning process generally employs photolithography. After the portion of the anode 131 not to be etched is protected by photoresist, the unwanted portion of the anode 131 material is etched, and the photoresist on the anode 131 is removed after the etching is completed. In this process, on the one hand, there is a situation where the above-mentioned photoresist is not removed cleanly, resulting in photoresist residue on the anode 131 causing abnormalities. On the other hand, since the etching process is generally completed in an atmospheric environment, the surface of the anode 131 is prone to oxidation during the etching process. In particular, during the oxidation process, areas where the surface of the anode 131 is uneven and has peaks or pinholes are more susceptible to oxidation, thereby increasing the contact resistance between the anode 131 and the light-emitting functional layer 132.

In the previous embodiment of the present disclosure, although the plurality of first partition structures 122 utilized also partition the anode auxiliary electrode 134, the residual problem caused by etching the anode 131 may not be addressed, and the contact interface between the anode auxiliary electrode 134 and the light-emitting functional layer 132 may only be improved by setting the anode auxiliary electrode 134. However, when significant residue issues exist on the anode 131, it leads to a poor film interface between the anode 131 and the anode auxiliary electrode 134, thereby affecting the light-emitting efficiency. In some embodiments, in addition to having the ability to isolate the anode auxiliary electrode 134, the plurality of second partition structures 141 may further protect the anode 131 from the above-mentioned residual problem during the etching process of the anode 131.

Specifically, the display panel 100 further includes a partition layer 140, the partition layer 140 is disposed below the pixel-defining layer 120 and disposed on the anode 134, and the partition layer 140 is in direct contact with the anode 131. In an orthographic projection on the substrate, a projection boundary of the partition layer 140 is within a projection range of the pixel-defining layer 120 in an orthographic projection on the substrate, and a preset distance w as shown in FIG. 4 is provided between an outermost projection boundary of the partition layer 140 and an outermost projection boundary of the pixel-defining layer 120, each of the plurality of second partition structures 141 is formed by the pixel-defining layer 120 and the partition layer 140. The preset distance is greater than or equal to 5,000 angstroms and less than or equal to 50,000 angstroms, and a thickness of the partition layer is greater than or equal to 100angstroms and less than or equal to 10,000 angstroms.

In some embodiments, the plurality of second partition structures 141 are formed by adding a partition layer 140 between the pixel-defining layer 120 and the anode 131, so that the partition layer 140 is at the bottom and has a width greater than the width of the pixel-defining layer 120, and the edge of the pixel-defining layer 120 protrudes from the partition layer 140. The plurality of second partition structures 141 are respectively arranged around each opening area 101, and when the anode auxiliary electrode 134 is evaporated, the redundant anode auxiliary electrode 134 material on the pixel-defining layer 120 is disconnected from the anode 131, so that the anode auxiliary electrode 134 is independently arranged.

Specifically, each of the plurality of second partition structures 141 is configured to separate the anode auxiliary electrodes 134 of two adjacent light-emitting elements 130 when the anode auxiliary electrode 134 is deposited over the entire surface. Each of the plurality of first partition structures 122 is configured to separate the light-emitting functional layer 132 of two adjacent light-emitting elements 130 when the light-emitting functional layer 130 is deposited over the entire surface, and the cathode is connected to the conductive portions of two adjacent first partition structures. The conductive portion 1221 of the plurality of first partition structures 122 is also configured to connect the cathodes 133 of two adjacent light-emitting elements 130. The plurality of second partition structures 141 are located below the plurality of first partition structures 122, and under the projection of the substrate 110, the plurality of first partition structures 122 are closer to the plurality of opening areas 101 than the plurality of first partition structures 122, so that when the anode auxiliary electrode 134 is isolated, the anode auxiliary electrode 134 is directly disconnected from the edge of the pixel-defining layer 120. Moreover, considering that when the plurality of first partition structures 122 act independently, the patterning process of the anode 131 may not be protected by the partition layer 140. When the plurality of second partition structures 141 act independently, since the pixel-defining layer 120 in the mask-less evaporation technology is formed of inorganic material, it is difficult for its thickness to support its ability to isolate the light-emitting functional layer 132. Therefore, in some embodiments, by combining the advantages of the plurality of first partition structures 122 and the plurality of second partition structures 141, the disadvantages of each of the two when implemented alone are overcome, thereby improving the luminous efficiency and service life of the plurality of light-emitting elements 130 without adding additional complex processes.

The main function of the partition layer 140 is to protect the anode 131 during the patterning process of the anode 131. Specifically, in the process of forming the anode 131, it is necessary to form independently set the anode 131 in the plurality of opening areas 101, and the anode 131 and the partition layer 140 set on the anode 131 are etched at the same time, and the anode 131 is protected by the partition layer 140. That is, in the process of etching the anode 131, there is no need to make the photoresist directly contact the anode 131, but to set it on the partition layer 140 to etch the partition layer 140 and the anode 131 at the same time, so that the partition groove 121 is formed in the non-opening area 102, so that the anode 131 is set independently. The pixel-defining layer 120 is configured to insulate the location of the partition groove 121, and the pixel-defining layer 120 partially overlaps with the anode 131 and the partition layer 140, and the pixel-defining layer 120 is set to define the plurality of opening areas 101, that is, the areas where the plurality of light-emitting elements 130 are set.

In some embodiments, the partition layer 140 is provided to cover the anode 131. In the process of etching the anode 131, the photoresist is provided on the partition layer 140, thus the anode 131 does not contact the photoresist, thereby avoiding the residual problem caused by the unclean film stripping of the photoresist material on the anode 131. Moreover, the partition layer 140 is etched again in the subsequent process of forming the partition structure, so that the anode 131 is exposed in the opening area 101, so that the anode 131 may directly contact the subsequent anode auxiliary electrode 134 in the opening area 101. By providing the partition layer 140, the problem of photoresist residue in the etching process of the anode 131 is improved in the process of forming the partition structure. In addition, with the addition of the partition layer 140 to form the partition structure, although the etching technology is employed, neither the etching of the partition layer 140 nor the etching of the partition structure requires additional photomasks, and both may be directly completed using the current process machine, which is suitable for the production of current production lines.

Each of the plurality of light-emitting elements 130 in the display panel 100 may generally be controlled individually. The specific method is to connect the anode 131 of the plurality of light-emitting elements 130 to a thin film transistor respectively, and drive it through the pixel driving circuit. When the pixel driving circuit assigns different voltages to the anode 131, the plurality of light-emitting elements 130 are controlled to have different light brightness. The pixel driving circuit of the display panel 100 is formed by thin film technology, the pixel driving circuit may also be called a pixel driving layer 150, the pixel driving layer 150 is generally arranged on the substrate 110 and under the anode 131. The pixel driving layer 150 is generally formed of multiple metal layers and insulating layers to form thin film transistors, driving circuits, etc., so as to realize the control of the plurality of light-emitting elements 130.

Since each of the anodes 131 of the plurality of light-emitting elements 130 needs to be connected to the corresponding thin film transistor, generally speaking, they are connected through a via hole, and an extension line of the anode 131 is connected to the thin film transistor through the via hole. In some embodiments, the position of the via hole may be set corresponding to the position of the above-mentioned partition layer 140. That is, on the orthographic projection of the substrate 110, the projection of the via hole between the anode 131 of the current light-emitting unit 130 and the thin film transistor overlaps with the projection of the partition layer 140. The resistance at the via hole is reduced through the conductive effect of the partition layer 140.

In the process of forming the plurality of second partition structures 141, the material of the partition layer 140 may be metal material or metal alloy material, but it is different from the material used for the anode 131. The main consideration is that in the process of etching the partition layer 140 to form the pixel-defining layer 120, a wet etching process is generally required. The partition layer 140 is side-etched, since the wet etching process is an isotropic process, so that the edge of the pixel-defining layer 120 protrudes from the partition layer 140, thereby forming a partition structure. In the process of etching, if the anode 131 and the partition layer 140 are made of the same material, the corresponding anode 131 is also etched, causing the anode 131 to be etched and damaged. The etching solution only reacts with the material of the partition layer 140, and does not react with the material of the anode 131, therefore the anode 131 is not affected, when the anode 131 and the partition layer 140 are made of different materials, since the etching solution only etches the corresponding material, that is, during the etching process,.

In some embodiments, considering that the plurality of second partition structures 141 formed by the pixel-defining layer 120 and the partition layer 140 has limited partitioning capability, its partitioning capability is mainly related to the preset distance and the thickness of the partition layer 140, and the preset distance and the thickness of the partition layer 140 may not completely isolate the light-emitting functional layer 132. In some embodiments, the light-emitting functional layer 132 is mainly isolated by the plurality of first partition structures 122.

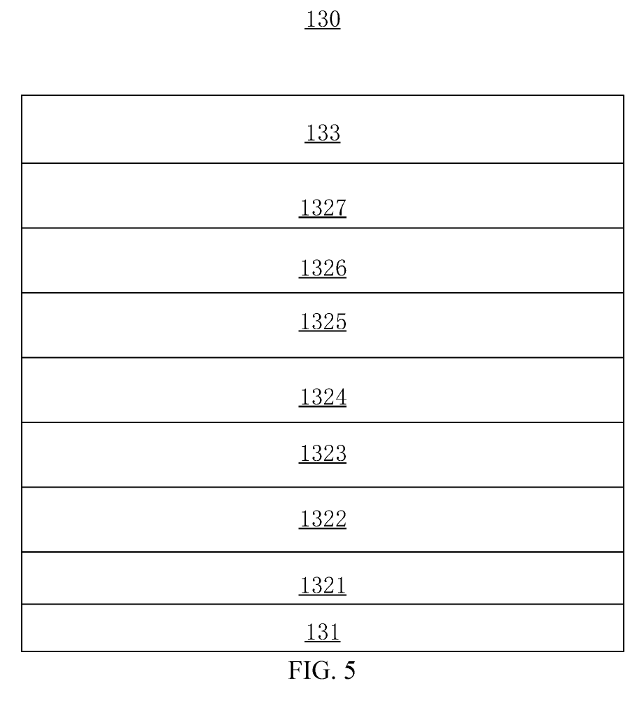

FIG. 5 is a schematic diagram of a light-emitting element of a first embodiment of the present disclosure. As shown in FIG. 5, the light-emitting functional layer 132, from the anode 131 to the cathode 133, respectively includes multiple film-layer structures such as a hole-injection layer 1321, a hole-transport layer 1322, an electron-blocking layer 1323, a light-emitting layer 1324, a hole-blocking layer 1325, an electron-transport layer 1326, and an electron-injection layer 1327. The electron-injection layer 1327 is disposed on the side of the cathode 133, and the hole-injection layer 1321 is disposed on the side of the anode 131. In some embodiments, the plurality of first partition structures 122 partitions the above-mentioned film layers in sequence.

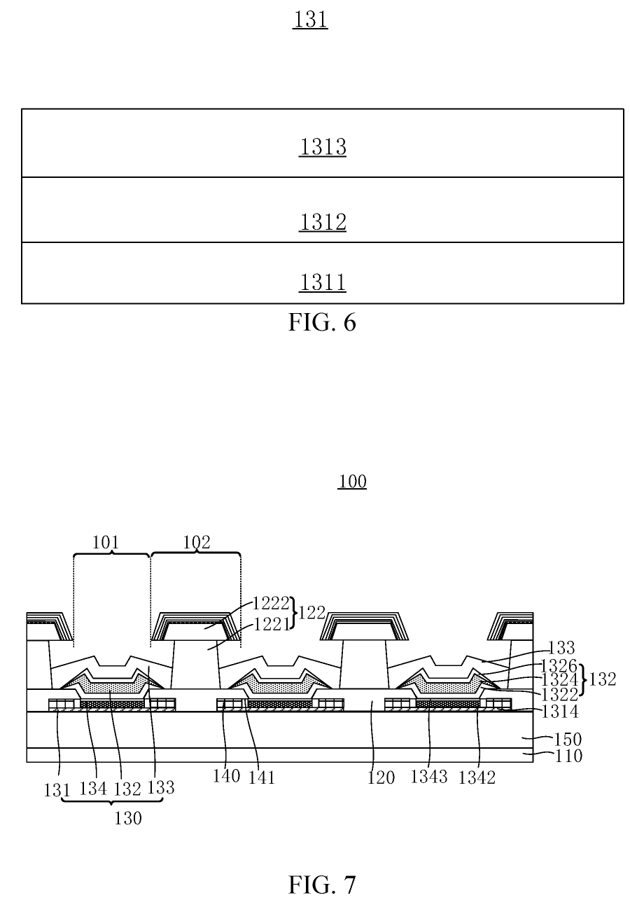

FIG. 6 is a schematic diagram of an anode of a second embodiment of the present disclosure. As shown in FIG. 6, in some embodiments, the anode 131 includes a first transparent electrode layer 1311, a first reflective electrode layer 1312 and a second transparent electrode layer 1313. The first reflective electrode layer 1312 is disposed between the first transparent electrode layer 1311 and the second transparent electrode layer 1313; the first reflective electrode layer 1312 is formed of reflective metal material. The anode auxiliary electrode 134 includes a first auxiliary electrode layer 1341. The first auxiliary electrode layer 1341 is disposed on the second transparent electrode layer 1313 and is in direct contact with the second transparent electrode layer 1313. The plurality of second partition structures 141 are configured to separate the first auxiliary electrode layers 1341 of two adjacent light-emitting elements 130.

For the display panel 100 currently based on organic light-emitting materials, the anode 131 is generally arranged in a sandwich configuration, that is, the first reflective electrode layer 1312 is sandwiched between the first transparent electrode layer 1311 and the second transparent electrode layer 1313, so as to protect the first reflective electrode layer 1312. On the other hand, since the first transparent electrode layer 1311 is generally formed of metal oxides such as indium tin oxide (hereinafter referred to as ITO), the indium tin oxide has a higher work function, the plurality of light-emitting elements 130 generate more holes on the anode 131 side, thereby improving the light-emitting efficiency of the plurality of light-emitting elements 130. In some embodiments, the anode 131 is a three-layer electrode layer of ITO, silver (Ag), and ITO. The corresponding material of the partition layer 140 may be a metal oxide such as indium zinc oxide (hereinafter referred to as IZO), metals such as aluminum (Al), molybdenum (Mo), copper (Cu), or an alloy of the above metals with other metals.

In some embodiments, the first auxiliary electrode layer 1341 may be selected from metal oxide materials with a high work function, such as ITO and IZO, or may be selected from high-work-function metals or metal alloy materials such as Pt, Ni, and Au. However, considering that metals or metal alloy materials are opaque when their thickness is relatively large, it is necessary to limit the thickness of the metals or metal alloy materials. That is, the thickness of the first auxiliary electrode layer 1341 should not exceed 30 nm (300 angstroms). Of course, the thickness of the first auxiliary electrode layer 1341 should not be too thin, and it needs to be at least 10 Å. Among them, under the orthographic projection of the substrate 110, the projection of the anode auxiliary electrode 134 is within the projection range of the anode 131.

FIG. 7 is a schematic diagram of another display panel of a second embodiment of the present disclosure. As shown in FIG. 6, in some embodiments, due to the protective effect of the partition layer 140 on the anode 131, the anode 131 is set to be a single-layer electrode layer. When etching the partition groove 121 in the three-layer anode and by the pixel-defining layer 120 to insulate the anode 131, the metals in the three-layer sandwich structure are not easy to etch, and problems such as over-etching or incomplete etching are likely to occur. Therefore, the anode 131 is set to be a single-layer metal layer. The anode 131 includes a first electrode layer 1314, and the first electrode layer 1314 is formed of one or more of metal, metal alloy, or metal oxide.

The first electrode layer 1314 may be any one of the above-mentioned three layers of ITO, Ag, and ITO. When the first electrode layer 1314 is a silver electrode layer, it may also serve as a reflective metal layer.

The anode auxiliary electrode 134 includes a second reflective electrode layer 1342 and a second auxiliary electrode layer 1343 when the anode 131 is a single layer. The second reflective electrode layer 1342 is formed of silver material or silver-alloy material. The second reflective electrode layer 1342 is disposed on the anode 131 and is in direct contact with the anode 131. The second auxiliary electrode layer 1343 is formed of metal oxide. The second auxiliary electrode layer 1343 is disposed on the second reflective electrode layer 1342 and is in direct contact with the second reflective electrode layer 1342. The plurality of second partition structures 141 are configured to partition the second reflective electrode layers 1342 and the second auxiliary electrode layers 1343 of two adjacent light-emitting elements 130.

The second reflective electrode layer 1342 is set within the anode auxiliary electrode 134. That is, the reflective metal layer of the anode 131 is formed by mask-less evaporation technology, specifically by using a partition structure, in a vacuum environment, in the same environment as the light-emitting functional layer 132. The manufacturing process of the reflective metal layer no longer requires an etching step. Besides the advantages mentioned above, this may further improve the film quality of the reflective metal layer, that is, the second reflective electrode layer 1342.

Specifically, in order to ensure the reflection quality of the second reflective electrode layer 1342, the thickness of the second reflective electrode layer 1342 is greater than or equal to 1,000 angstroms. Considering that the second reflective electrode layer 1342 generally needs to be formed of reflective metal, such as one or both of a magnesium material and silver material, and considering the isolation capability of the isolation structure, the thickness of the second reflective electrode layer 1342 needs to be less than or equal to 5,000 angstroms. Considering the actual situation, a suitable thickness may be selected from 1,500 angstroms to 3,000 angstroms.

In some embodiments, the second auxiliary electrode layer 1343 may be formed of a transparent electrode layer, such as ITO or IZO material. The anode 131 and the anode auxiliary electrode 134 serve as the driving electrode on one side of the plurality of light-emitting elements 130. The three-layer sandwich structure ITO/IZO, Ag/Mg, and ITO/IZO formed by the combination of the anode 131 and the anode auxiliary electrode 134 has a good driving ability for the light-emitting functional layer 132.

In some embodiments, the second auxiliary electrode layer 1343 may be formed of silver oxide or magnesium oxide. The material of the second auxiliary electrode layer 1343 mainly depends on the material of the second reflective electrode layer 1342.

The second auxiliary electrode layer 1343 is formed by plasma-treating a surface of the first reflective electrode layer 1312 away from the substrate 110 to form a metal oxide film layer as the second auxiliary electrode layer 1343. When the second reflective electrode layer 1342 is a silver electrode, the second auxiliary electrode layer 1343 is a silver oxide electrode. When the second reflective electrode layer 1342 is a magnesium electrode, the second auxiliary electrode layer 1343 is a magnesium oxide electrode.

In some embodiments, after the second reflective electrode layer 1342 is vacuum-deposited, the surface of the second reflective electrode layer 1342 close to the cathode 133 may be oxidized by plasma treatment, thereby forming a thinner metal oxide layer on one side, and the metal oxide layer serves as the second auxiliary electrode layer 1343. Taking silver material as an example, the second reflective electrode is a silver electrode, and the second auxiliary electrode layer 1343 is silver oxide (Ag₂O). The work function of the silver oxide rises to 4.8eV to 5.1eV, which may better match the HOMO (5eV to 6eV) of the organic material in the light-emitting functional layer 132. In this way, the film interface performance between the anode 131 and the light-emitting functional layer 132 is improved while reducing the difficulty of the anode 131 process, thereby improving the efficiency and service life of the plurality of light-emitting elements 130.

In some embodiments, the process sequence in some embodiments is basically the same as that in the previous embodiment, and the difference lies in the use of materials for the anode 131 and the anode auxiliary electrode 134. When the material of the second auxiliary electrode layer 1343 is an oxide of the material of the second reflective electrode layer 1342, the following steps are further included: after the process of the second reflective electrode layer 1342 in the anode auxiliary electrode 134 is completed, the surface of the second reflective electrode layer 1342 in the plurality of opening areas 101 is subjected to plasma treatment, so that the surface of the second reflective electrode layer 1342 is oxidized to form a metal oxide as the second auxiliary electrode layer 1343.

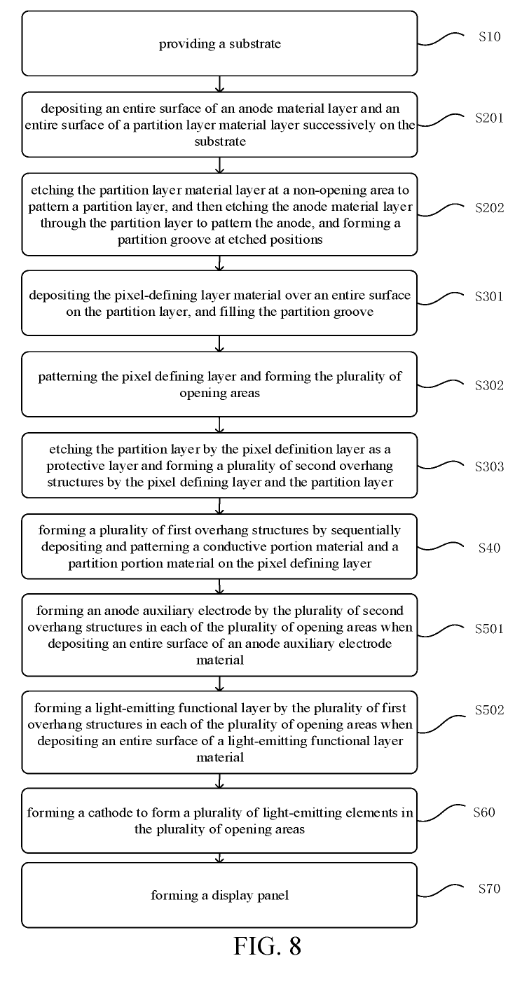

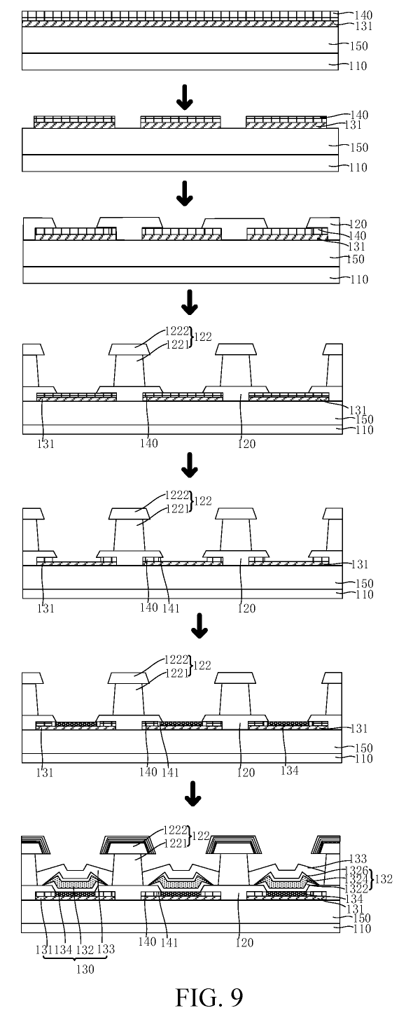

FIG. 8 is a schematic diagram of steps of a method for manufacturing a display panel according to the second embodiment of the present disclosure. FIG. 9 is a schematic diagram of manufacturing a display panel according to a second embodiment of the present disclosure. As shown in FIGS. 8 and 9, the present disclosure further discloses a method for manufacturing a display panel corresponding to the above-mentioned display panel. The method for manufacturing a display panel includes:

S10: providing a substrate;

S201: depositing an entire surface of an anode material layer and an entire surface of a partition layer material layer successively on the substrate;

S202: etching the partition layer material layer at a non-opening area to pattern a partition layer, and then etching the anode material layer through the partition layer to pattern the anode, and forming a partition groove at etched positions;

S301: depositing the pixel-defining layer material over an entire surface on the partition layer, and filling the partition groove;

S302: patterning the pixel-defining layer and forming the plurality of opening areas, wherein a radial width of the pixel definition layer is greater than that of the partition groove;

S303: etching the partition layer by the pixel definition layer as a protective layer and forming a plurality of second partition structures by the pixel-defining layer and the partition layer; and in an orthographic projection on the substrate, a projection boundary of the partition layer is within a projection range of the pixel-defining layer, a preset distance is provided between an outermost projection boundary of the partition layer and an outermost projection boundary of the pixel-defining layer;

S40: forming a plurality of first partition structures by sequentially depositing and patterning a conductive portion material and a partition portion material on the pixel-defining layer;

S501: forming an anode auxiliary electrode by the plurality of second partition structures in each of the plurality of opening areas when depositing an entire surface of an anode auxiliary electrode material;

S502: forming a light-emitting functional layer by the plurality of first partition structures in each of the plurality of opening areas when depositing an entire surface of a light-emitting functional layer material;

S60: forming a cathode to form a plurality of light-emitting elements in the plurality of opening areas; and

S70: forming a display panel.

In some embodiments, by adding a partition layer 140 without the need for an additional photomask, on the one hand, the etching protection of the anode 131 is achieved, and the plurality of second partition structures 141 are formed to cooperate with the plurality of first partition structures 122 to respectively achieve the isolation of the anode auxiliary electrode 134 and the light-emitting functional layer 132, thereby improving the overall yield of the display panel 100 by optimizing the process.

The above steps S501 to S60 may be repeated when the plurality of light-emitting elements 130 are of different colors. Taking the red light-emitting elements as an example, after completing the process of the plurality of first partition structures 122, the anode auxiliary electrode 134 is vacuum-deposited in the plurality of opening areas 101 where the red light-emitting elements are located, which are referred to as the red sub-pixel areas, and the multiple film layers in the light-emitting functional layer 132 are vacuum-deposited in sequence, and finally the cathode 133 is deposited, thereby realizing the process of the red light-emitting elements. After completing the process of the red light-emitting elements, due to the mask-less evaporation technology, a plurality of green sub-pixel areas and a plurality of blue sub-pixel areas form red light-emitting elements respectively. Therefore, it is also necessary to remove the redundant materials in the green sub-pixel areas and the blue sub-pixel areas. The cathode 133, the light-emitting functional layer 132, and the anode auxiliary electrode 134 of the green sub-pixel and the blue sub-pixel may be removed by forming an etching protection layer, such as an inorganic encapsulation layer, at the position of the red sub-pixel through a patterned photolithography process. After completing the above process, repeat the process of forming a plurality of green light-emitting elements in the green sub-pixel area, removing the green light-emitting elements in other areas, and finally forming a plurality of blue light-emitting elements, then the encapsulation layer is utilized to encapsulate the light-emitting elements 130, and finally form other film layers to form the display panel 100.

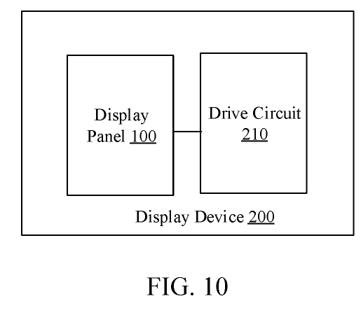

FIG. 10 is a schematic diagram of a display device according to the present disclosure. As shown in FIG. 10, the present disclosure further discloses a display device. The display device 200 includes a driving circuit 210 and any one of the display panels 100 in the above-mentioned embodiments 1 and 2. The driving circuit is configured to drive the display panel 100 to display.

It should be noted that the inventive concept of the present disclosure may be formed into many embodiments, but limitations of the application document preclude exhaustive listing. Therefore, should no conflict be present, the various embodiments or technical features described above may be arbitrarily combined to form new embodiments. After the various embodiments or technical features are combined, the original technical effects may be enhanced.

The foregoing content describes the present disclosure in further detail in conjunction with specific optional embodiments, but it should not be construed that the specific implementation of the present disclosure is limited solely to these descriptions. For those of ordinary skill in the art to which the present disclosure pertains, several simple deductions or replacements may be made without departing from the inventive concept of the present disclosure, and these should all be regarded as falling within the protection scope of the present disclosure.

What is claimed is:

1. A display panel, comprising:
a substrate;
a pixel-defining layer, disposed on the substrate and provided with a plurality of opening areas; and
a plurality of light-emitting elements, arranged in an array on the substrate and respectively located in the plurality of opening areas;
wherein each of the plurality of light-emitting elements comprises an anode, a light-emitting functional layer and a cathode, the anode is disposed on the substrate, the light-emitting functional layer is disposed on the anode, and the cathode is disposed on the light-emitting functional layer;
each of the plurality of light-emitting elements further comprises an anode auxiliary electrode, the anode auxiliary electrode is disposed between the anode and the light-emitting functional layer, the anode auxiliary electrode is formed of one or more of metal, metal alloy, or metal oxide; and
the display panel further comprises a plurality of first partition structures, disposed on the pixel-defining layer, each of the plurality of first partition structures comprises a conductive portion and a partition portion, the partition portion is disposed on the conductive portion, a radial width of the partition portion is greater than that of the conductive portion, and each of the plurality of first partition structures is configured to separate at least one of: (a) the anode auxiliary electrodes, (b) the light-emitting functional layers, of two adjacent light-emitting elements when depositing an entire surface of the anode auxiliary electrodes and the light-emitting functional layer.

2. The display panel according to claim 1, wherein each of the plurality of first partition structures is configured to separate the anode auxiliary electrodes and the light-emitting functional layer of two adjacent light-emitting elements when the anode auxiliary electrodes and the light-emitting functional layer are deposited over the entire surface; and
the anode auxiliary electrode and the light-emitting functional layer are respectively connected neither to the conductive portion, and the cathode is connected to the conductive portions of two adjacent first partition structures.

3. The display panel according to claim 1, wherein the display panel further comprises a plurality of second partition structures, the plurality of second partition structures are respectively disposed below the plurality of first partition structures;
each of the plurality of second partition structures is configured to separate the anode auxiliary electrodes of two adjacent light-emitting elements when the anode auxiliary electrodes are deposited over the entire surface; and
each of the plurality of first partition structures is configured to separate the light-emitting functional layer of two adjacent light-emitting elements when the light-emitting functional layer is deposited over the entire surface, and the cathode is connected to the conductive portions of two adjacent first partition structures.

4. The display panel according to claim 3, wherein the display panel further comprises a partition layer, the partition layer is disposed below the pixel-defining layer and disposed on the anode, and the partition layer is in direct contact with the anode; and
in an orthographic projection on the substrate, a projection boundary of the partition layer is within a projection range of the pixel-defining layer, a preset distance is provided between an outermost projection boundary of the partition layer and an outermost projection boundary of the pixel-defining layer, each of the plurality of second partition structures is formed by the pixel-defining layer and the partition layer, and the partition layer is configured to protect the anode during a patterning process of the anode.

5. The display panel according to claim 4, wherein the partition layer is formed of metal or metal alloy materials, and the partition layer is formed of different materials from the anode.

6. The display panel according to claim 4, wherein the preset distance is greater than or equal to 5,000 angstroms and less than or equal to 50,000 angstroms, and a thickness of the partition layer is greater than or equal to 100 angstroms and less than or equal to 10,000 angstroms.

7. The display panel according to claim 4, wherein the anode comprises a first transparent electrode layer, a first reflective electrode layer, and a second transparent electrode layer, and the first reflective electrode layer is disposed between the first transparent electrode layer and the second transparent electrode layer; the first reflective electrode layer is formed of reflective metal material.

8. The display panel according to claim 7, wherein the anode auxiliary electrode comprises a first auxiliary electrode layer, the first auxiliary electrode layer is disposed on the second transparent electrode layer and is in direct contact with the second transparent electrode layer.

9. The display panel according to claim 8, wherein a thickness of the first auxiliary electrode layer is from 10 angstroms to 300 angstroms;
the second partition structure is configured to separate the first auxiliary electrode layers of two adjacent light-emitting elements; and
a projection boundary of the anode auxiliary electrode is within a projection range of the anode in the orthographic projection on the substrate.

10. The display panel according to claim 4, wherein the anode comprises a first electrode layer, and the first electrode layer is formed of one or more of metal, metal alloy, or metal oxide;
the anode auxiliary electrode comprises a second reflective electrode layer and a second auxiliary electrode layer, the second reflective electrode layer is formed of silver material or silver-alloy material, the second reflective electrode layer is disposed on the anode and is in direct contact with the anode, the second auxiliary electrode layer is formed of metal oxides, and the second auxiliary electrode layer is disposed on the second reflective electrode layer and is in direct contact with the second reflective electrode layer; and
the second partition structure is configured to separate the second reflective electrode layers of two adjacent light-emitting elements.

11. The display panel according to claim 10, wherein a thickness of the second reflective electrode layer is from 1,000 angstroms to 5,000 angstroms; and
the second auxiliary electrode layer is formed by plasma-treating a surface of the first reflective electrode layer away from the substrate to form a metal oxide film layer as the second auxiliary electrode layer.

12. A method for manufacturing a display panel, comprising:
providing a substrate;
forming an anode by depositing and patterning on the substrate;
forming a pixel-defining layer by depositing and patterning, and forming a plurality of opening areas;
forming a plurality of first partition structures by sequentially depositing and patterning a conductive portion material and a partition portion material on the pixel-defining layer;
forming, by depositing an anode auxiliary electrode material and a light-emitting functional layer material, an anode auxiliary electrode and a light-emitting functional layer in each of the plurality of opening areas through the plurality of first partition structures;
forming a cathode to form a plurality of light-emitting elements in the plurality of opening areas; and
forming a display panel.

13. The method for manufacturing a display panel according to claim 12, wherein the forming the anode by depositing and patterning on the substrate comprises:
depositing an entire surface of an anode material layer and an entire surface of a partition layer material layer successively on the substrate;
etching the partition layer material layer at a non-opening area to pattern a partition layer, and then etching the anode material layer through the partition layer to pattern the anode, and forming a partition groove at etched positions.

14. The method for manufacturing a display panel according to claim 13, wherein the forming a pixel-defining layer by depositing and patterning, and forming a plurality of opening areas comprises:
depositing pixel-defining layer material over an entire surface on the partition layer, and filling the partition groove;
patterning the pixel-defining layer and forming the plurality of opening areas, wherein a radial width of the pixel definition layer is greater than that of the partition groove;
etching the partition layer by the pixel definition layer as a protective layer and forming a plurality of second partition structures by the pixel-defining layer and the partition layer;
wherein in an orthographic projection on the substrate, a projection boundary of the partition layer is within a projection range of the pixel-defining layer, a preset distance is provided between an outermost projection boundary of the partition layer and an outermost projection boundary of the pixel-defining layer.

15. The method for manufacturing a display panel according to claim 14, wherein the forming an anode auxiliary electrode and a light-emitting functional layer in each of the plurality of opening areas through the plurality of first partition structures by depositing an anode auxiliary electrode material and a light-emitting functional layer material comprises:
forming an anode auxiliary electrode by the plurality of second partition structures in each of the plurality of opening areas when depositing an entire surface of anode auxiliary electrode material;
forming a light-emitting functional layer by the plurality of first partition structures in each of the plurality of opening areas when depositing an entire surface of light-emitting functional layer material.

16. The method for manufacturing a display panel according to claim 15, wherein the anode comprises a first transparent electrode layer, a first reflective electrode layer, and a second transparent electrode layer, and the first reflective electrode layer is disposed between the first transparent electrode layer and the second transparent electrode layer; the first reflective electrode layer is formed of reflective metal material;
the anode auxiliary electrode comprises a first auxiliary electrode layer, the first auxiliary electrode layer is disposed on the second transparent electrode layer and is in direct contact with the second transparent electrode layer; and
the second partition structure is configured to separate the first auxiliary electrode layers of two adjacent light-emitting elements.

17. The method for manufacturing a display panel according to claim 15, wherein the anode comprises a first electrode layer, and the first electrode layer is formed of one or more of metal, metal alloy, or metal oxide;
the anode auxiliary electrode comprises a second reflective electrode layer and a second auxiliary electrode layer, the second reflective electrode layer is formed of silver material or silver-alloy material, the second reflective electrode layer is disposed on the anode and is in direct contact with the anode, the second auxiliary electrode layer is formed of metal oxides, and the second auxiliary electrode layer is disposed on the second reflective electrode layer and is in direct contact with the second reflective electrode layer; and
the second partition structure is configured to separate the second reflective electrode layers of two adjacent light-emitting elements.

18. A display device, comprising a display panel and a driving circuit configured to drive the display panel; wherein the display panel comprises:
a substrate;
a pixel-defining layer, disposed on the substrate and provided with a plurality of opening areas; and
a plurality of light-emitting elements, arranged in an array on the substrate and respectively located in the plurality of opening areas;
wherein each of the plurality of light-emitting elements comprises an anode, a light-emitting functional layer and a cathode, the anode is disposed on the substrate, the light-emitting functional layer is disposed on the anode, and the cathode is disposed on the light-emitting functional layer;
each of the plurality of light-emitting elements further comprises an anode auxiliary electrode, the anode auxiliary electrode is disposed between the anode and the light-emitting functional layer, the anode auxiliary electrode is formed of one or more of metal, metal alloy, or metal oxide; and
the display panel further comprises a plurality of first partition structures, disposed on the pixel-defining layer, each of the plurality of first partition structures comprises a conductive portion and a partition portion, the partition portion is disposed on the conductive portion, the radial width of the partition portion is greater than that of the conductive portion, and each of the plurality of first partition structures is configured to separate at least one of: (a) the anode auxiliary electrodes, (b) the light-emitting functional layers, of two adjacent light-emitting elements when depositing an entire surface of the anode auxiliary electrodes and the light-emitting functional layer.
